(19) United States
(12) Patent Application Publication
(10) Pub. No.: US 2011/0042689 A1
(43) Pub. Date: Feb. 24, 2011

(54) Semiconductor light-emitting element array device, image exposing device, image forming apparatus, and image display apparatus

(75) Inventors: Takahito Suzuki, Gunma (JP); Mitsuhiko Ogihara, Gunma (JP)

Correspondence Address: RABIN & Berdo, PC, 1101 14TH STREET, NW, SUITE 500, WASHINGTON, DC, 20005, US

(73) Assignee: OKI DATA CORPORATION, Tokyo (JP)

(21) Appl. No.: 12/805,618

(22) Filed: Aug. 10, 2010

(30) Foreign Application Priority Data
Aug. 24, 2009 (JP) 2009-193065

(51) Int. Cl. H01L 33/02; H01L 33/00; H01L 33/62

(52) U.S. Cl. 257/80; 257/88; 257/E33.005; 257/E33.055; 257/E33.077

(57) ABSTRACT

A semiconductor light-emitting element array device includes a substrate; a plurality of removable layers being disposed on the substrate; and a thin-film semiconductor light-emitting device being disposed on each of the plurality of removable layers, being made of a different material from a surface material of the substrate, and having a semiconductor light-emitting element; wherein the plurality of removable layers are made of a material which is capable of being etched by a selective chemical etching process. An image exposing device includes an image exposing unit including the semiconductor light-emitting element array device. An image exposing device includes an image exposing unit including the semiconductor light-emitting element array device. An image display apparatus includes an image display unit including the semiconductor light-emitting element array device.

### BACKGROUND OF THE INVENTION

1. Field of the Invention

The present invention relates to a semiconductor light-emitting element array device including a plurality of semiconductor light-emitting elements which are regularly arranged, an image exposing device including the semiconductor light-emitting element array device, an image forming apparatus including the image exposing device, and an image display apparatus including the semiconductor light-emitting element array device.

2. Description of the Related Art

In general, in order to stack a semiconductor light-emitting element on a different-material substrate which is made of a material different from the semiconductor light-emitting element, a semiconductor light-emitting element chip (e.g., 250 to 300 μm thickness) is made by dicing or cleavage, the semiconductor light-emitting element chip is fixed to the substrate with a die bonding paste, an adhesive agent, or the like, and a connecting pad of the semiconductor light-emitting element chip is electrically connected with an electric wiring on the different-material substrate through the use of an Au bonding wire. It is also known that the semiconductor light-emitting element chip and a driving IC chip are bonded on the substrate and these two chips are electrically connected through the use of the Au bonding wire. However, according to these techniques, it is difficult to shrink the size of the semiconductor light-emitting element chip sufficiently, because the chip is formed by dicing or cleavage. Moreover, each of the semiconductor light-emitting element chip and the driving IC chip requires the connecting pad (e.g., 50 μm×50 μm or more) for connecting the Au bonding wire, and so it is difficult to shrink the size of the chips sufficiently.

Japanese Patent Publication No. 3813123 (Patent Document 1) proposes a technical scheme that an LED epitaxial film (having a thickness of 5 μm or less, for example) which is a thin-film light emitting device and includes semiconductor light-emitting elements is closely bonded to a substrate, and an electrode layer of the thin-film light emitting device is connected with an electric wiring on the substrate through the use of a wiring layer which can be formed by a combination of photolithography with deposition or sputtering. According to the technical scheme, the thin-film light emitting device can be formed without dicing or cleavage and the thin-film light emitting device can be sufficiently shrank in size, because no connection pad for connecting a bonding wire is needed.

However, in the apparatus of Patent Document 1, even if a defect (e.g., defective stacking or defective external shape) is found in a part (e.g., only one device) in a plurality of thin-film light emitting devices which are closely fixed to the substrate, it is difficult to repair only the defective part and the whole of the apparatus is usually discarded.

A reason for the problem is explained as follows: the thin-film light emitting device which is closely fixed to the substrate is made of a material which is difficult to be selectively etched by chemical etching, such as (AlₓGa₁₋ₓ₎_{y}In_{1-y}P, GaP, GaN, AlₓGa₁₋ₓN, or InₓGa₁₋ₓN. When the thin-film light emitting device is bonded to a bonding surface which is made of an inorganic material such as SiO₂ or SiN, a metal material such as Au or Pd, or an organic material such as polyimide, acryl, SOG, or novolac, it is difficult to remove the thin-film light emitting device from the substrate without damage to the bonding surface.

Another reason for the problem is explained as follows: even if the thin-film light emitting device is made of a material, which is capable of being etched by a selective chemical etching process, such as AlₓGa₁₋ₓAs or GaAs, after the thin-film light emitting device is removed by chemical etching, a surface of the substrate is rough as a result of the removal, and it is difficult to fix a new thin-film light emitting device closely thereto once again.

### SUMMARY OF THE INVENTION

Thus, it is an object of the present invention to provide a semiconductor light-emitting element array device in which a plurality of semiconductor light-emitting elements which are regularly arranged can be partially exchanged, an image exposing device, an image exposing device including the semiconductor light-emitting element array device, an image forming apparatus including the image exposing device, and an image display apparatus including the semiconductor light-emitting element array device.

According to an aspect of the present invention, a semiconductor light-emitting element array device includes a substrate; a plurality of removable layers being disposed on the substrate; and a thin-film semiconductor light-emitting device being disposed on each of the plurality of removable layers, being made of a different material from a surface material of the substrate, and having a semiconductor light-emitting element; wherein the plurality of removable layers are made of a material which is capable of being etched by a selective chemical etching process.

According to another aspect of the present invention, an image exposing device includes an image exposing unit including the semiconductor light-emitting element array device.

According to a further aspect of the present invention, an image exposing device includes an image exposing unit including the semiconductor light-emitting element array device.

According to a still further aspect of the present invention, an image display apparatus includes an image display unit including the semiconductor light-emitting element array device.

According to the present invention, by inserting a removable layer which is capable of being etched by a selective chemical etching process between a substrate of the semiconductor light-emitting element array device and a thin-film light emitting device, even if the thin-film light emitting device is made of a material which is difficult to be chemically etched, the fixed thin-film light emitting device can be removed from the substrate without damage to the surface material of the substrate. Therefore, if a defect such as defective bonding or defective external shape is found in a thin-film light emitting device which is fixed to the substrate, only the defective thin-film light emitting device can be exchanged for a new thin-film light emitting device, and therefore manufacturing yield of final perfect product can be improved.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a longitudinal sectional view schematically illustrating a structure of a main part of a semiconductor light-emitting element array device according to a first embodiment of the present invention, before a wiring layer is formed;

FIG. 2 is a plan view schematically illustrating the structure of the main part of the semiconductor light-emitting element array device of FIG. 1;

FIG. 3 is a longitudinal sectional view schematically illustrating a structure of the main part of the semiconductor light-emitting element array device according to the first embodiment of the present invention, after the wiring layer is formed;

FIG. 4 is a plan view schematically illustrating the structure of the main part of the semiconductor light-emitting element array device of FIG. 3;

FIG. 5 is a plan view schematically illustrating a structure of an image exposing device which includes the semiconductor light-emitting element array device according to the first embodiment;

FIG. 6 is an enlarged plan view illustrating an example of the main part of FIG. 5;

FIG. 7 is an enlarged plan view illustrating another example of the main part of FIG. 5;

FIG. 8 is a plan view schematically illustrating a structure of an image display apparatus which includes the semiconductor light-emitting element array device according to the first embodiment;

FIG. 9 is an enlarged plan view illustrating an example of a main part of FIG. 8;

FIGS. 10A to 10E are plan views illustrating exchanging steps of defective thin-film light emitting devices in the semiconductor light-emitting element array device according to the first embodiment;

FIG. 11 is a longitudinal sectional view schematically illustrating a structure of a main part of a semiconductor light-emitting element array device according to a second embodiment of the present invention, before a wiring layer is formed;

FIG. 12 is a plan view schematically illustrating the structure of the main part of the semiconductor light-emitting element array device of FIG. 11;

FIG. 13 is a longitudinal sectional view schematically illustrating a structure of the main part of the semiconductor light-emitting element array device according to the second embodiment of the present invention, after the wiring layer is formed;

FIG. 14 is a plan view schematically illustrating the structure of the main part of the semiconductor light-emitting element array device of FIG. 13;

FIG. 15 is a longitudinal sectional view schematically illustrating a structure of a main part of a semiconductor light-emitting element array device according to a third embodiment of the present invention, before a wiring layer is formed;

FIG. 16 is a plan view schematically illustrating the structure of the main part of the semiconductor light-emitting element array device of FIG. 15;

FIG. 17 is a longitudinal sectional view schematically illustrating a structure of the main part of the semiconductor light-emitting element array device according to the third embodiment, after the wiring layer is formed;

FIG. 18 is a plan view schematically illustrating the structure of the main part of the semiconductor light-emitting element array device of FIG. 17; and

FIG. 19 shows a full-color LED printer as an image forming apparatus.

### DETAILED DESCRIPTION OF THE INVENTION

Further scope of applicability of the present invention will become apparent from the detailed description given hereinafter. However, it should be understood that the detailed description and specific examples, while indicating preferred embodiments of the invention, are given by way of illustration only, since various changes and modifications will become apparent to those skilled in the art from the detailed description.

### First Embodiment

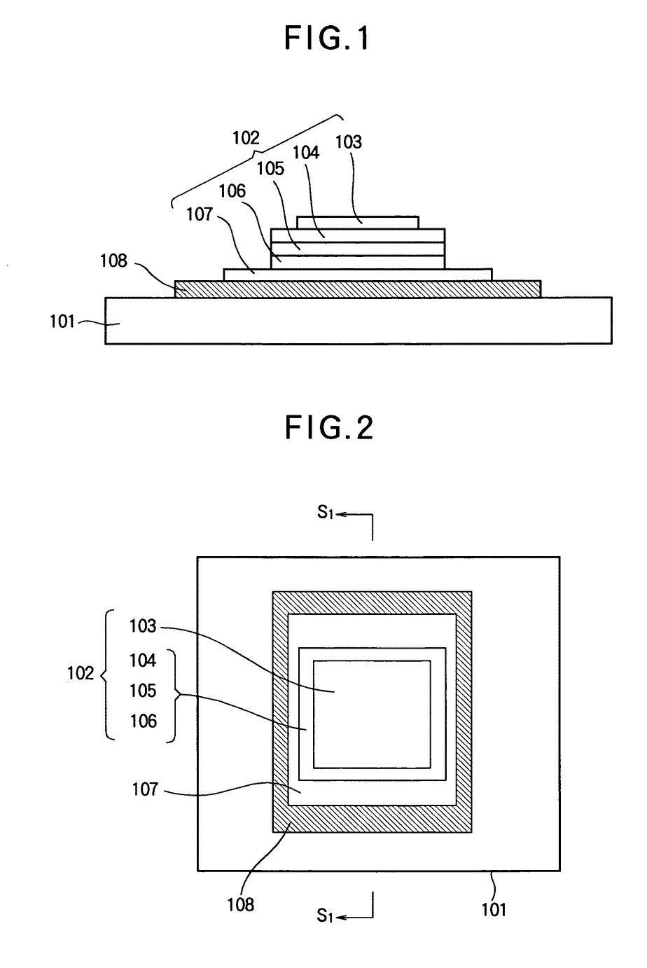

FIG. 1 is a longitudinal sectional view schematically illustrating a structure of a main part of a semiconductor light-emitting element array device according to a first embodiment of the present invention, before a wiring layer is formed; and FIG. 2 is a plan view schematically illustrating the structure of the main part of the semiconductor light-emitting element array device of FIG. 1. FIG. 1 illustrates a sectional view taken along a line S₁-S₁ of FIG. 2.

As FIGS. 1 and 2 illustrate, the semiconductor light-emitting element array device according to the first embodiment has an integrated substrate 101; a plurality of removable layers 108 which are disposed on the integrated substrate 101 (FIGS. 1 and 2 illustrate only one of the removable layers 108); and a thin-film light emitting device 102 which is disposed on each of the plurality of removable layers 108 and is made of a material different from the integrated substrate 101.

As illustrated in FIG. 1, the thin-film light emitting device 102 includes, in an order from the top, an upper contact layer 103, an upper clad layer 104, an active layer 105, a lower clad layer 106, and a lower contact layer 107. The thin-film light emitting device 102 can be made of a compound semiconductor, such as InP, InₓGa₁₋ₓP, GaAs, AlₓGa₁₋ₓAs, GaP, (AlₓGa₁₋ₓ)_{y}In_{1-y}P, AlₓIn₁₋ₓP, GaN, InₓGa₁₋ₓN, AlₓGa₁₋ₓN, AlN, or the like. The thin-film light emitting device 102 has a thickness of 5 μm or less, for example. Here, x and y satisfy 0<x<1 and 0<y<1.

The thin-film light emitting device 102 is manufactured and mounted through the following steps, for example: the upper contact layer 103, the upper clad layer 104, the active layer 105, the lower clad layer 106, and the lower contact layer 107 are formed in the order, on a substrate for manufacturing the semiconductor light emitting element (e.g., an epitaxial growth substrate which is not illustrated in the drawings), by a method such as metalorganic chemical vapor deposition (MOCVD), metalorganic vapor phase epitaxy (MOVPE), molecular beam epitaxy (MBE), or the like, and thus the thin-film light emitting device is formed. The thin-film light emitting device is removed from the substrate for manufacturing the semiconductor light emitting element (not illustrated in the drawings) by chemical lift-off, laser lift-off, or the like. The removed thin-film light emitting device is mounted on the removable layer 108 on the integrated substrate 101, if necessary, after a polishing process.

Between the thin-film light emitting device 102 and the integrated substrate 101, the removable layer 108 is formed. The removable layer 108 is made of a material which is capable of being etched by a selective chemical etching process without damage to the material of the integrated substrate 101 or a passivation film (not illustrated in the drawings) which forms a surface of the integrated substrate. The removable layer 108 is divided into a plurality of pieces on the integrated substrate 101 so that each of the pieces is larger than the thin-film light emitting device 102 in size. It is desirable that a thickness of the removable layer 108 be within a range from 50 nm to 1000 nm. A reason for the thickness of the removable layer 108 is as follows: if the removable layer 108 is less than 50 nm in thickness, an etchant is difficult to permeate the removable layer 108 at the time of the removal and the removal takes a long time. On the other hand, if the removable layer 108 is more than 1000 nm in thickness, it is difficult to form the removable layer 108 which has a surface roughness of 5 nm or less and it is expected that sufficient intermolecular force cannot be obtained.

If the integrated substrate 101 or the passivation film (not illustrated in the drawings) which forms the surface of the integrated substrate 101 is made of a material such as SiN or SiO₂, an inorganic material such as AlN or Al₂O₃, or a metal material such as Al, Ni, Cu, Cr, Ti, or Au can be used as a material of the removable layer 108, for example. If the removable layer 108 is an AlN or Al₂O₃ layer, a hot phosphoric acid can be used as an etchant, for example. If the removable layer 108 is an Al or Ni layer, a mixed solution of phosphoric acid, nitric acid, acetic acid, and pure water can be used as an etchant, for example. If the removable layer 108 is a Cu layer, a mixed solution of acetic acid, aqueous hydrogen peroxide, and pure water can be used as an etchant, for example. If the removable layer 108 is a Cr or Ti layer, a hydrofluoric acid solution (or a buffer solution of hydrofluoric acid) or a mixed solution of hydrochloric acid, nitric acid, and pure water can be used as an etchant, for example. If the removable layer 108 is an Au layer, an iodine-based etchant can be used as an etchant, for example.

If the integrated substrate 101 or the passivation film (not illustrated in the drawings) which forms the surface of the integrated substrate 101 is made of AlN or Al₂O₃, an inorganic material such as SiN or SiO₂, or a metal material such as Al, Ni, Cu, Cr, Ti, or Au can be used as a material of the removable layer 108, for example. If the removable layer 108 is a SiN or SiO₂ layer, a hydrofluoric acid solution (or a buffer solution of hydrofluoric acid) can be used as an etchant, for example. If the removable layer 108 is an Al or Ni layer, a mixed solution of phosphoric acid, nitric acid, acetic acid, and pure water can be used as an etchant. If the removable layer 108 is a Cu layer, a mixed solution of acetic acid, aqueous hydrogen peroxide, and pure water can be used as an etchant, for example. If the removable layer 108 is a Cr or Ti layer, a mixed solution of hydrochloric acid, nitric acid, and pure water can be used as an etchant, for example. If the removable layer 108 is an Au layer, an iodine-based etchant can be used as an etchant, for example.

It is desirable that a surface of the removable layer 108 on which the thin-film light emitting device 102 is disposed have a surface roughness of 5 nm or less. The thin-film light emitting device 102 is closely bonded to the removable layer 108 by any of intermolecular force bonding, hydrogen bonding, anodic bonding, and an adhesive agent such as an epoxy.

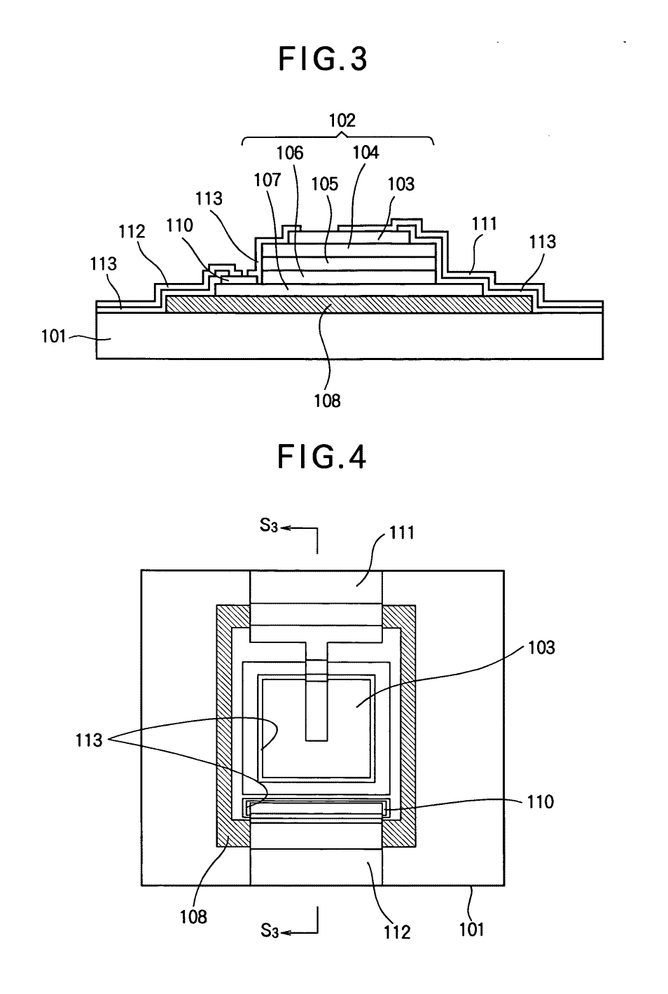

FIG. 3 is a longitudinal sectional view schematically illustrating a structure of the main part of the semiconductor light-emitting element array device according to the first embodiment, after the wiring layer is formed; and FIG. 4 is a plan view schematically illustrating the structure of the main part of the semiconductor light-emitting element array device of FIG. 3. FIG. 3 illustrates a sectional view taken along a line S₃-S₃ of FIG. 4.

If there is no problem in the structure of the device illustrated in FIGS. 1 and 2 (there is no defect such as defective stacking or defective shape, for example), a lower electrode pad 110 is formed on the lower contact layer 107 as illustrated in FIGS. 3 and 4. In this example which is explained here, the structure of the thin-film light emitting device 102 is formed before stacked on the integrated substrate 101, that is, the layers from the upper contact layer 103 to the lower clad layer 106 are etched so that the lower contact layer 107 exposes on the epitaxial growth substrate (not illustrated in the drawings) in the thin-film light emitting device 102, and then the thin-film light emitting device 102 which has the structure is stacked on the substrate. However, the structure can be formed even after the thin-film light emitting device 102 is stacked on the integrated substrate 101. The lower electrode pad 110 can be formed in a predetermined position in the thin-film light emitting device 102 on the epitaxial growth substrate (not illustrated in the drawings), before the thin film is formed.

After the lower electrode pad 110 is formed, an interlayer insulating film 113 is formed on the thin-film light emitting device 102. The interlayer insulating film 113 is an inorganic insulating film such as a SiN film or a SiO₂ film, or an organic insulating film such as a polyimide film, a novolac film or an acryl film. Then, an upper electrode connecting wiring 111 and a lower electrode connecting wiring 112 are formed on the interlayer insulating film 113, and the upper contact layer 103 and the lower electrode pad 110 are thereby connected with common wiring (not illustrated in the drawings) which is formed in advance on the integrated substrate 101. As an alternative, a connection pad may be formed on the integrated substrate 101. The upper electrode connecting wiring 111, the lower electrode connecting wiring 112, or the lower electrode pad 110 can be formed by a well-known method such as deposition, sputtering, or the like.

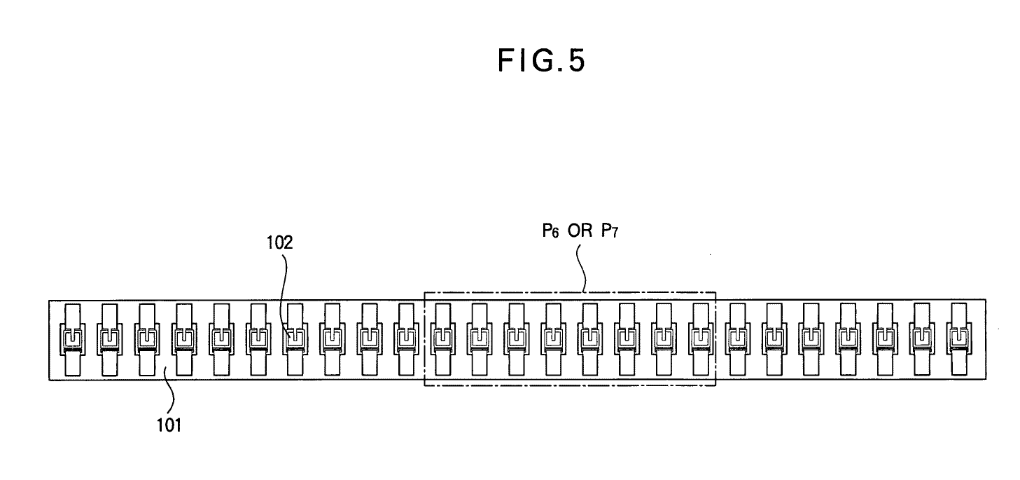

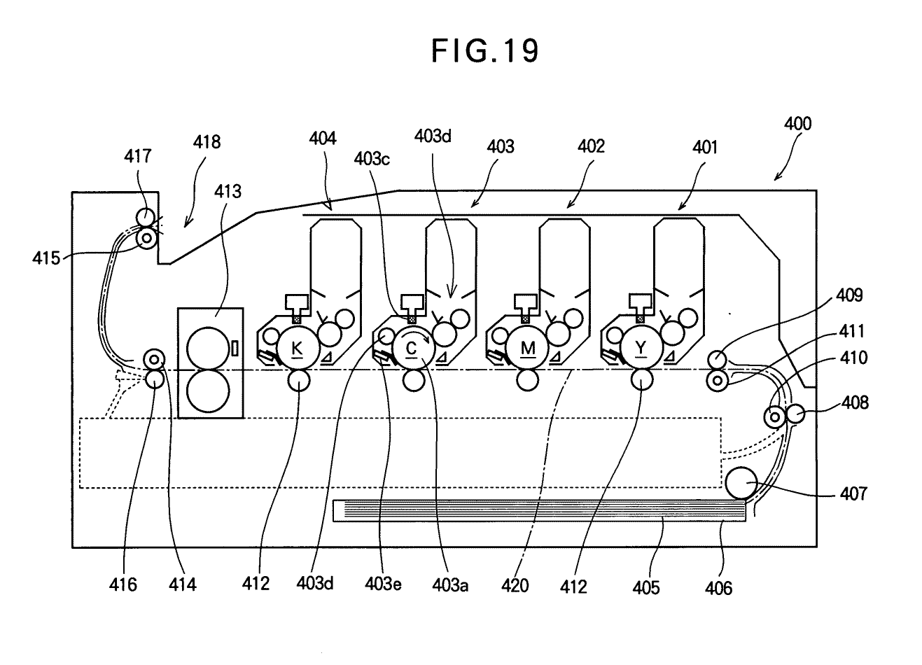

FIG. 5 is a plan view schematically illustrating a structure of an image exposing device which includes the semiconductor light-emitting element array device according to the first embodiment. The image exposing device of FIG. 5 has the structure that a plurality of thin-film light emitting devices 102 is arranged in one-dimensional array (or linearly) on the integrated substrate 101. The image exposing device is a device for forming an electrostatic latent image on a surface of a photosensitive body in an electrophotographic image forming apparatus, for example, an LED print head for an LED printer, which will be described below with reference to FIG. 19.

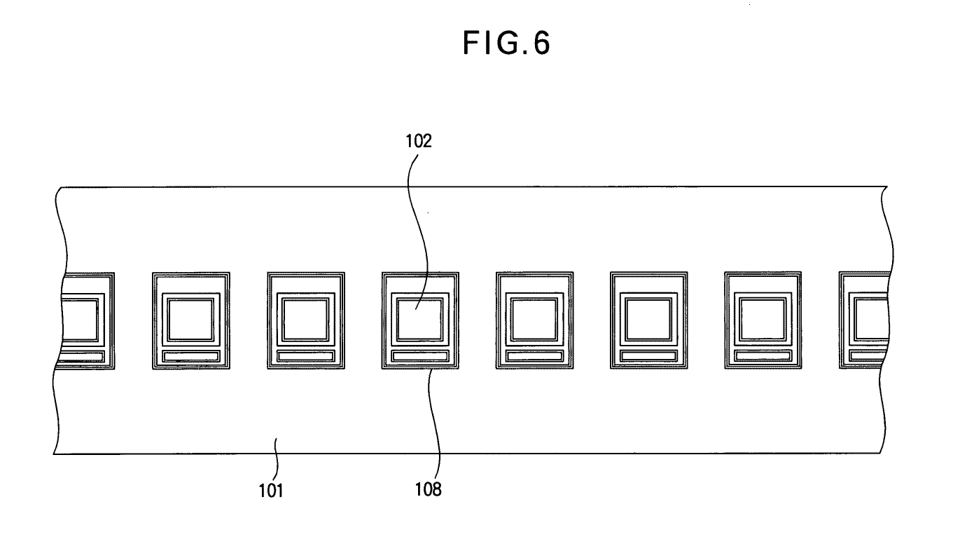

FIG. 6 is an enlarged plan view illustrating an example of a main part P₆ of FIG. 5. If the plurality of thin-film light emitting devices 102 are arranged in one-dimensional array on the integrated substrate 101 as illustrated in FIG. 6, the thin-film light emitting device 102 is formed for every light-emitting dot and each of the thin-film light emitting devices 102 is disposed on each of the removable layers 108. In this case, the thin-film light emitting device 102 can be exchanged one by one.

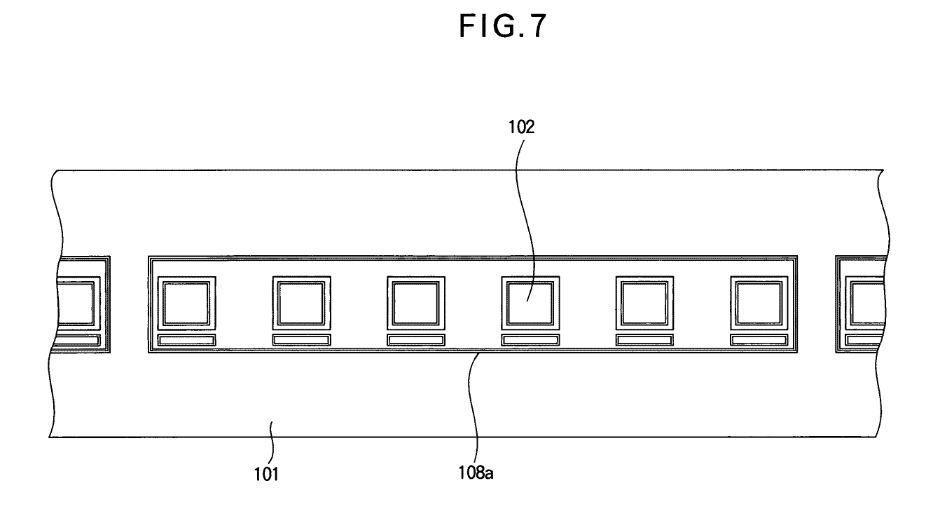

FIG. 7 is an enlarged plan view illustrating an example of a main part P₇ of FIG. 5. If the plurality of thin-film light emitting devices 102 are arranged in one-dimensional array on the integrated substrate 101 as illustrated in FIG. 7, the thin-film light emitting device 102 is formed for every light-emitting dot and the plurality of thin-film light emitting devices 102 may be disposed on a removable layer 108a. In this case, a plurality of the thin-film light emitting devices 102 can be exchanged as a unit (in FIG. 7, a single unit includes six thin-film light emitting devices 102).

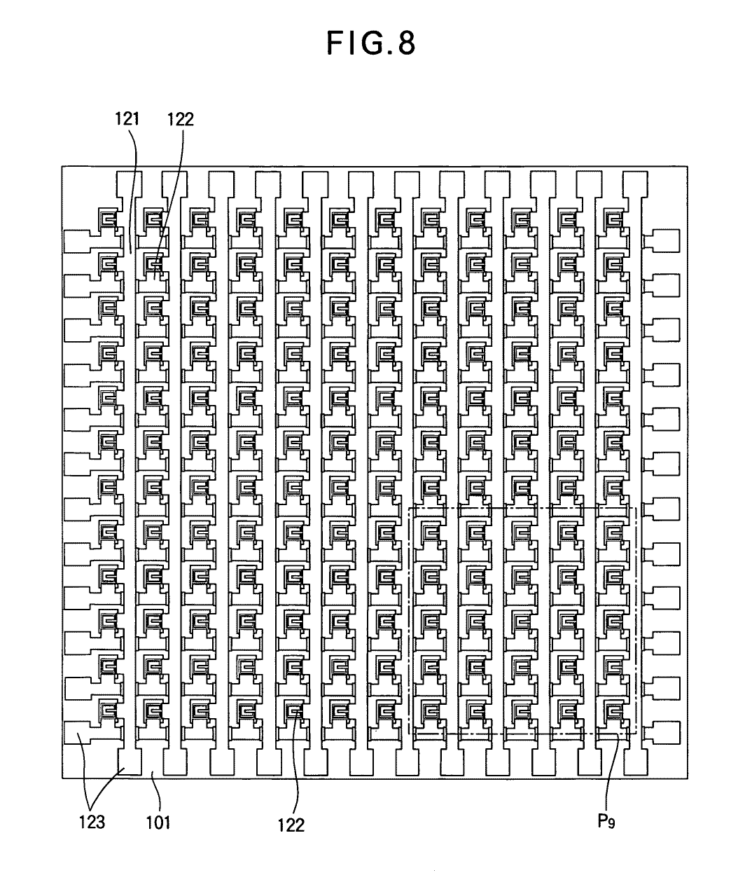

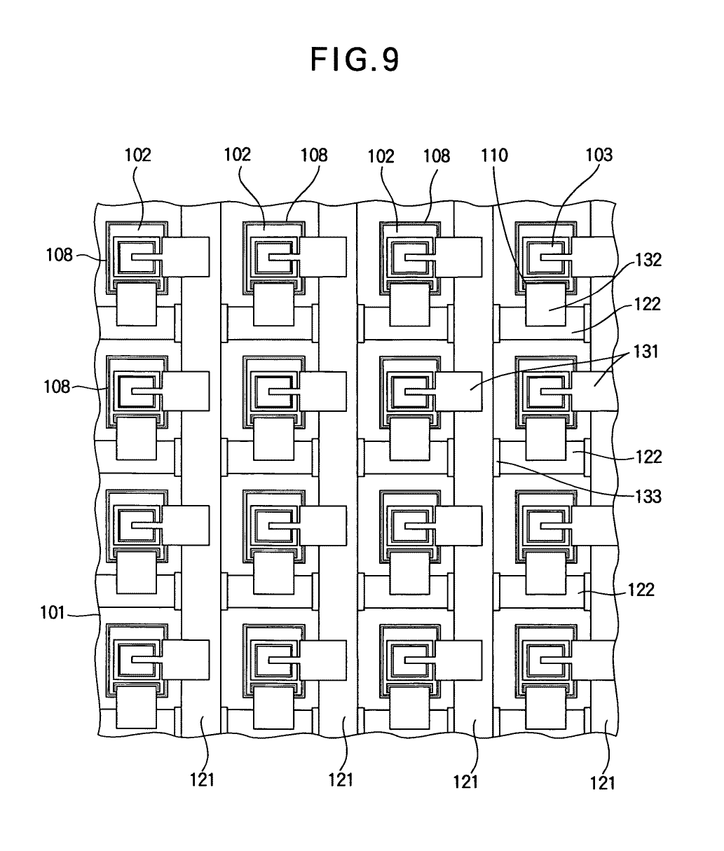

FIG. 8 is a plan view schematically illustrating a structure of an image display apparatus which includes the semiconductor light-emitting element array device according to the first embodiment; and FIG. 9 is an enlarged plan view illustrating an example of a main part P₉ of FIG. 8. The image display apparatus, such as an LED display, includes the plurality of thin-film light emitting devices 102 which are arranged in two-dimensional array on the integrated substrate 101 as illustrated in FIGS. 8 and 9. Firstly, the thin-film light emitting devices 102 is mounted in two-dimensional array on the integrated substrate 101, an upper electrode common wiring 121 which is formed on the integrated substrate 101 is connected with the upper contact layer 103 which is formed on the thin-film light emitting device 102 through the use of upper electrode connecting wiring 131, and a lower electrode common wiring 122 is connected with the lower electrode pad 110 which is formed on the thin-film light emitting device 102 through the use of a lower electrode connecting wiring 132. The upper electrode common wiring 121 and the upper electrode connecting wiring 131 can be formed as a single structure, and the lower electrode common wiring 122 and the lower electrode connecting wiring 132 can be formed as a single structure.

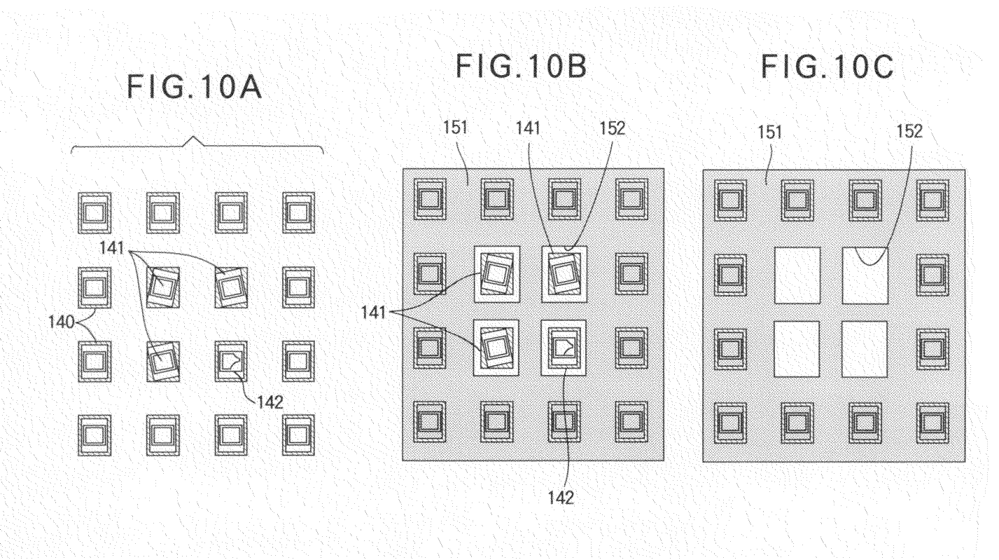

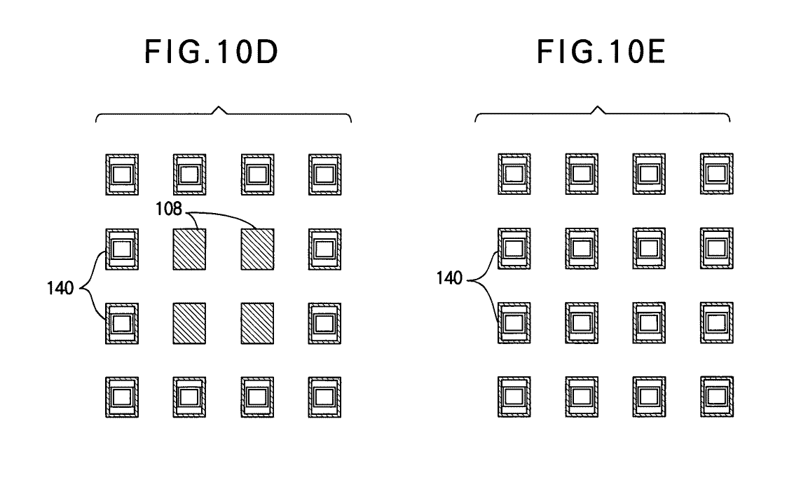

FIGS. 10A to 10D are plan views illustrating exchanging steps of defective thin-film light emitting devices in the semiconductor light-emitting element array device according to the first embodiment. In a case that the thin-film light emitting devices 102 are made of a material which is difficult to be chemically etched, such as AlₓGa₁₋ₓAs, GaAs, (AlₓGa₁₋ₓ)_{y}In_{1-y}P, GaN, AlGaN, or InGaN, the removable layer 108 which is capable of being etched by a selective chemical etching process is inserted between the integrated substrate 101 and the thin-film light emitting devices 102. Then, if one of the thin-film light emitting devices 102 is defectively stacked or is recognized to have a defective shape, the removable layer 108 on which the defective thin-film light emitting device 102 is disposed is selectively removed, and thus the defective thin-film light emitting device 102 thereon can be removed. In another case that the thin-film light emitting devices 102 are made of a material which can be chemically etched, such as GaAs or AlₓGa₁₋ₓAs, the thin-film light emitting device 102 can be removed in parallel with a step of removing a bonding surface which denatures or changes its shape as a result of bonding. After the defective thin-film light emitting device 102 is removed in the manner, a surface of the integrated substrate 101 (a surface from which the defective thin-film light emitting device 102 is removed) is smooth, thus another removable layer 108 is formed thereon, and another thin-film light emitting device 102 can be closely fixed on the removable layer 108.

FIG. 10A illustrates a step of checking positions of defective thin-film light emitting device (also referred to as ‘defective stacking dots’) 141 which are determined to be defectively stacked and another defective thin-film light emitting device (also referred to as ‘defective shape dot’) 142 which is determined to have a defective shape. At the next step illustrated in FIG. 10B, the overall array device is coated with a positive photoresist, only portions of the defective stacking dots 141 and the defective shape dot 142 which are checked at the step of FIG. 10A are exposed, and then developing is implemented. Through this step, a mask resist 151 can be formed so that only the portions of the defective stacking dots 141 and the defective shape dot 142 which are checked at the step of FIG. 10A are opened (openings 152).

Next, the structural member which is manufactured at the step of FIG. 10B is dipped in an etchant by which only the removable layer 108 can be selectively etched. If the removable layer 108 is an Al or Al₂O₃ layer and the integrated substrate 101 or the passivation film (not illustrated in the drawings) mainly includes SiO₂ or SiN as a material, phosphoric acid which is heated to 85° C. can be used as an etchant. If the removable layer 108 is a SiO₂, SiN, or Ti layer and the integrated substrate 101 or the passivation film (not illustrated in the drawings) is an Al₂O₃ layer, only the removable layer 108 can be selectively removed by using BHF (buffered hydrofluoric acid) or HF (hydrofluoric acid) as an etchant. FIG. 10C illustrates a state after the thin-film light emitting devices are removed by removing the removable layers 108.

Next, after the mask resist 151 is removed, the removable layers 108 are newly formed in the positions from which the defective thin-film light emitting devices are removed, as illustrated in FIG. 10D. Finally, as illustrated in FIG. 10E, the thin-film light emitting devices 102 are mounted on the newly-formed removable layers 108.

As described above, in the semiconductor light-emitting element array device, the image exposing device, the image forming apparatus and the image display apparatus according to the first embodiment, the removable layer 108 which is capable of being etched by a selective chemical etching process is inserted between the integrated substrate 101 and the thin-film light emitting device 102 of the semiconductor light-emitting element array device, thereby even if the thin-film light emitting device 102 is made of a material which is difficult to be chemically etched, the fixed thin-film light emitting device 102 can be removed from the integrated substrate 101 without damage to a surface material of the integrated substrate 101. Therefore, if a defect such as defective bonding or defective external shape is found in the thin-film light emitting device 102 which is fixed on the integrated substrate 101, only the defective thin-film light emitting device can be exchanged for a new thin-film light emitting device, and thus manufacturing yield of final perfect product can be improved.

### Second Embodiment

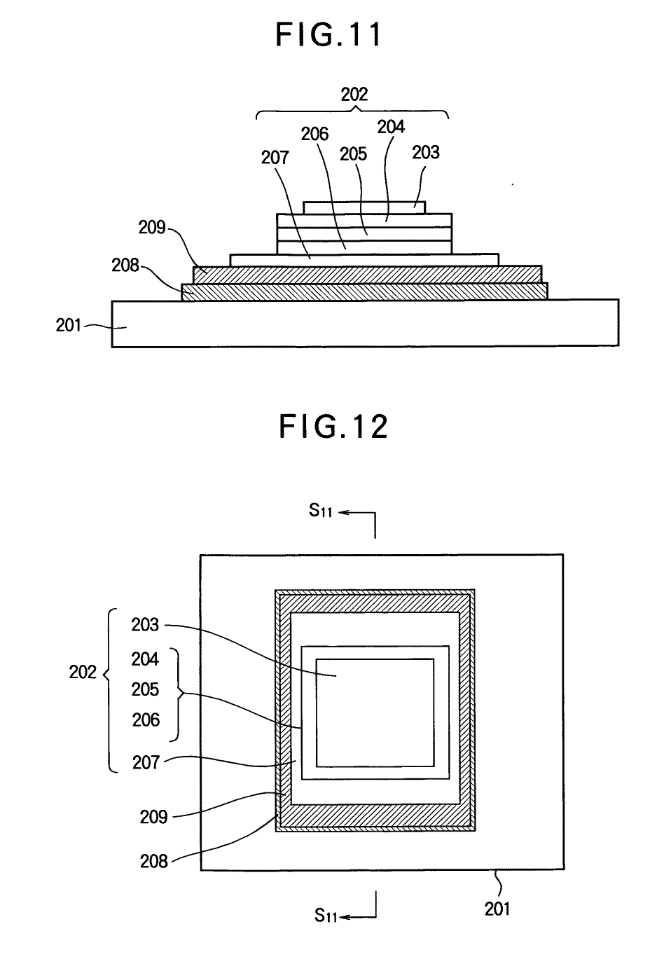

FIG. 11 is a longitudinal sectional view schematically illustrating a structure of a main part of a semiconductor light-emitting element array device according to a second embodiment of the present invention, before a wiring layer is formed; and FIG. 12 is a plan view schematically illustrating the structure of the main part of the semiconductor light-emitting element array device of FIG. 11. FIG. 11 illustrates a sectional view taken along a line S₁₁-S₁₁ of FIG. 12.

The semiconductor light-emitting element array device according to the second embodiment is different from the semiconductor light-emitting element array device according to the first embodiment in a point that a smoothing film 209 is added. An integrated substrate 201, a removable layer 208, and a thin-film light emitting device 202 in the semiconductor light-emitting element array device according to the second embodiment have the same structures as the integrated substrate 101, the removable layer 108, and the thin-film light emitting device 102 in the semiconductor light-emitting element array device according to the first embodiment, respectively. An upper contact layer 203, an upper clad layer 204, an active layer 205, a lower clad layer 206, and a lower contact layer 207 in the semiconductor light-emitting element array device according to the second embodiment have the same structures as the upper contact layer 103, the upper clad layer 104, the active layer 105, the lower clad layer 106, and the lower contact layer 107 in the semiconductor light-emitting element array device according to the first embodiment, respectively.

The smoothing film 209 can be formed on the removable layer 208 by coating which can reduce the surface roughness. The smoothing film 209 is an organic insulating film which is photosensitive or can be dry-etched, such as a polyimide, acryl, SOG (Spin On Glass), or novolac film. The smoothing film 209 is necessary to be formed smaller than the removable layer 208. The smoothing film 209 is formed not to be in contact with the integrated substrate 201 directly. It is desirable that the smoothing film 209 have a surface roughness of 5 nm or less. The smoothing film 209 and the thin-film light emitting device 202 are bonded to each other by any of intermolecular force bonding, hydrogen bonding, anodic bonding, and an adhesive agent such as an epoxy.

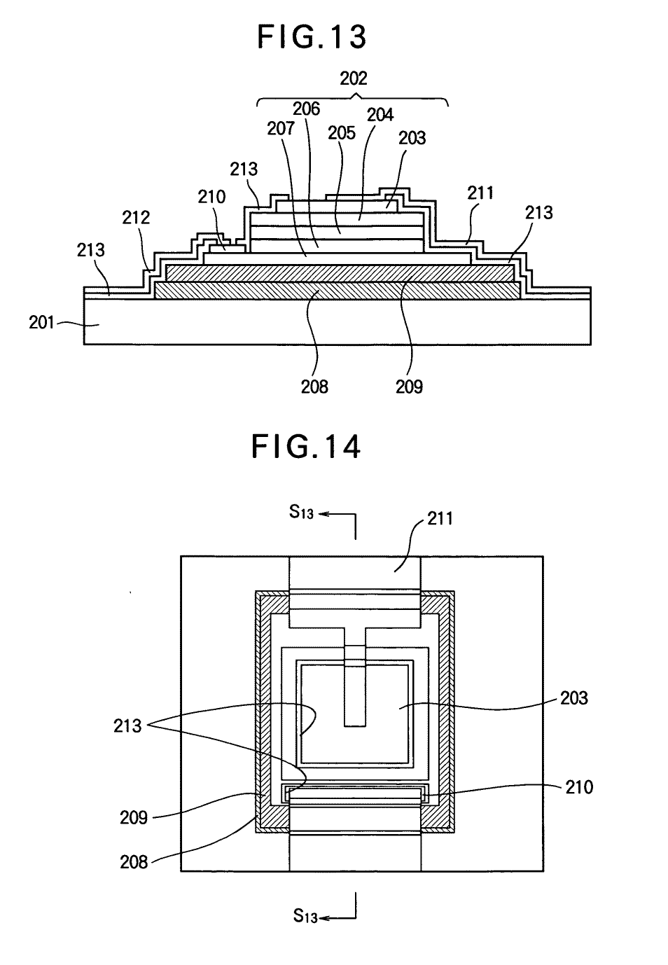

FIG. 13 is a longitudinal sectional view schematically illustrating a structure of the main part of the semiconductor light-emitting element array device according to the second embodiment, after the wiring layer is formed; and FIG. 14 is a plan view schematically illustrating the structure of the main part of the semiconductor light-emitting element array device of FIG. 2. FIG. 13 illustrates a sectional view taken along a line S₁₃-S₁₃ of FIG. 14.

A lower electrode pad 210, an upper electrode connecting wiring 211, a lower electrode connecting wiring 212, and an interlayer insulating film 213 in the semiconductor light-emitting element array device according to the second embodiment have the same structures as the lower electrode pad 110, the upper electrode connecting wiring 111, the lower electrode connecting wiring 112, and the interlayer insulating film 113 in the semiconductor light-emitting element array device according to the first embodiment, respectively.

According to the semiconductor light-emitting element array device of the second embodiment, by forming an organic insulating film which can be formed by coating, such as a polyimide, acryl, SOG, or novolac film, on the removable layer 208, the smoothing film 209 which has a surface roughness less than a typical surface roughness of the removable layer 208 can be formed. As a result, stronger intermolecular force bonding, hydrogen bonding, or anodic bonding can be obtained between the smoothing film 209 and the thin-film light emitting device 202 thereon. If the removable layer 208 is a metal layer, which is formed by a well-known method such as deposition or sputtering, such as a Ti or Al layer, it is extremely difficult to reduce the surface roughness and it may be difficult to stack by intermolecular force bonding, hydrogen bonding, or anodic bonding. Even if in such a case, stacking can be realized by inserting the smoothing film 209 of the present invention between the removable layer 208 and the thin-film light emitting device 202.

In the semiconductor light-emitting element array device according to the second embodiment, a defective dot can be repaired through the steps illustrated in FIGS. 10A to 10E, as well as in the semiconductor light-emitting element array device according to the first embodiment.

The semiconductor light-emitting element array device according to the second embodiment can be used to form an image exposing device, an image forming apparatus, and an image display apparatus, as well as in the first embodiment.

As described above, in the semiconductor light-emitting element array device, the image exposing device, the image forming apparatus, and the image display apparatus according to the second embodiment, the removable layer 208 which is capable of being etched by a selective chemical etching process and the smoothing film 209 are inserted between the integrated substrate 201 and the thin-film light emitting device 202 of the semiconductor light-emitting element array device, thereby even if the thin-film light emitting device 202 is made of a material which is difficult to be chemically etched, the fixed thin-film light emitting device 202 can be removed from the integrated substrate 201 without damage to a surface material of the integrated substrate 201. Therefore, if a defect such as defective bonding or defective external shape is found in the thin-film light emitting device 202 which is fixed on the integrated substrate 201, only the defective thin-film light emitting device can be replaced by a new thin-film light emitting device, and thus a manufacturing yield of final perfect product can be improved.

Except for the points described above, the second embodiment is the same as the first embodiment.

### Third Embodiment

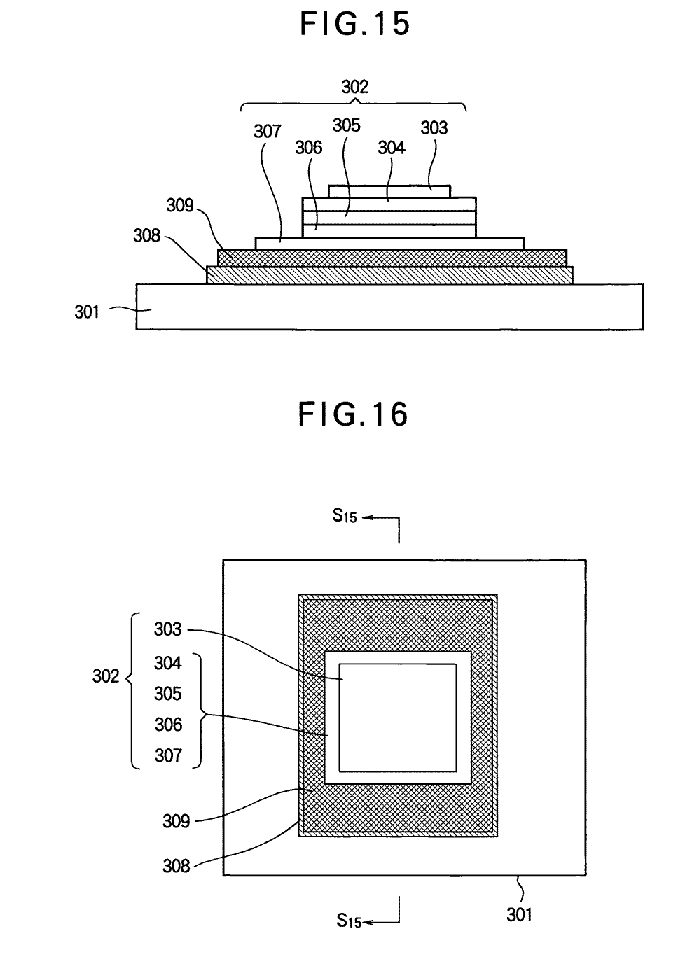

FIG. 15 is a longitudinal sectional view schematically illustrating a structure of a main part of a semiconductor light-emitting element array device according to a third embodiment of the present invention, before a wiring layer is formed; and FIG. 16 is a plan view schematically illustrating a structure of the main part of the semiconductor light-emitting element array device of FIG. 15. FIG. 15 illustrates a sectional view taken along a line S₁₅-S₁₅ of FIG. 16.

The semiconductor light-emitting element array device according to the third embodiment is difference from the semiconductor light-emitting element array device according to the first embodiment in a point that a bottom electrode surface 309 is added. An integrated substrate 301, a removable layer 308, and a thin-film light emitting device 302 in the semiconductor light-emitting element array device according to the third embodiment have the same structures as the integrated substrate 101, the removable layer 108, and the thin-film light emitting device 102 in the semiconductor light-emitting element array device according to the first embodiment, respectively. An upper contact layer 303, an upper clad layer 304, an active layer 305, a lower clad layer 306, and a lower contact layer 307 in the semiconductor light-emitting element array device according to the third embodiment have the same structures as the upper contact layer 103, the upper clad layer 104, the active layer 105, the lower clad layer 106, and the lower contact layer 107 in the semiconductor light-emitting element array device according to the first embodiment, respectively.

The bottom electrode layer 309 is formed on the removable layer 308 as a metal electrode layer which can make electrical contact with the lower contact layer 307 of the thin-film light emitting device 302. That is, an upper electrode is formed on a top surface of the thin-film light emitting device 302 and a lower electrode is formed on a bottom surface of the thin-film light emitting device 302. Thus, the thin-film light emitting device 302 needs no etching step to expose the lower contact layer 307 as described in the first and second embodiments, and the upper layer 303, the upper clad layer 304, the active layer 305, the lower clad layer 306, and the lower contact layer 307 can be formed to have the same size by etching. The bottom electrode layer 309 is formed to be smaller than the removable layer 308 in size. The bottom electrode layer 309 is formed not to be in contact with the integrated substrate 301 directly. The thin-film light emitting device 302 can be stacked on the bottom electrode layer 309 by intermolecular force bonding, hydrogen bonding, anodic bonding, or a conductive adhesive agent.

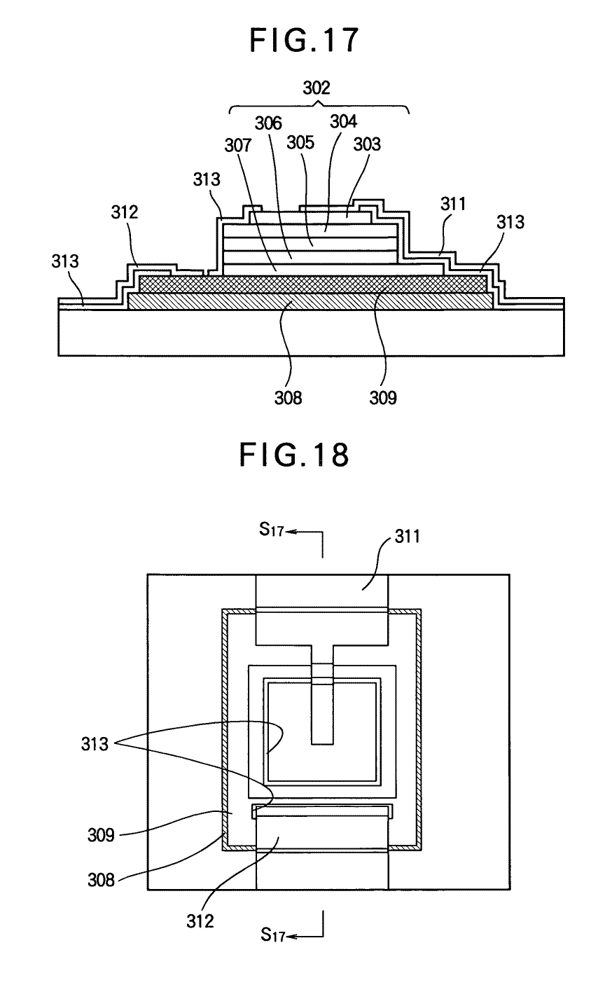

FIG. 17 is a longitudinal sectional view schematically illustrating a structure of the main part of the semiconductor light-emitting element array device according to the third embodiment, after the wiring layer is formed; and FIG. 18 is a plan view schematically illustrating a structure of the main part of the semiconductor light-emitting element array device of FIG. 17. FIG. 17 illustrates a sectional view taken along a line S₁₇-S₁₇ of FIG. 18.

An upper electrode connecting wiring 311, a lower electrode connecting wiring 312, and an interlayer insulating film 313 in the semiconductor light-emitting element array device according to the third embodiment have the same structures as the upper electrode connecting wiring 111, the lower electrode connecting wiring 112, and the interlayer insulating film 113 in the semiconductor light-emitting element array device according to the first embodiment, respectively.

According to the semiconductor light-emitting element array device of the third embodiment, a stacking surface is the bottom electrode layer 309 which is made of a metal material and can make electrical contact with the lower contact layer 307, thereby the lower electrode of the thin-film light emitting device 302 can be formed on the bottom surface of the thin-film light emitting device 302. Therefore, the structure of the thin-film light emitting device can be simplified and the thin-film light emitting device can be shrunk.

In the semiconductor light-emitting element array device according to the third embodiment, a defective dot can be repaired through the steps illustrated in FIGS. 10A to 10E, as well as in the semiconductor light-emitting element array device according to the first embodiment.

The semiconductor light-emitting element array device according to the third embodiment can be used to form an image exposing device, an image forming apparatus and an image display apparatus, as well as in the first embodiment.

As described above, in the semiconductor light-emitting element array device, the image exposing device, the image forming apparatus and the image display apparatus according to the third embodiment, the removable layer 308 which is capable of being etched by a selective chemical etching process is inserted between the integrated substrate 301 of the semiconductor light-emitting element array device and the bottom electrode layer 309 which is under the thin-film light emitting device 302, thereby even if the thin-film light emitting device 302 is made of a material which is difficult to be chemically etched, the fixed thin-film light emitting device 302 can be removed from the integrated substrate 301 without damage to a surface material of the integrated substrate 301. Therefore, if a defect such as defective bonding or defective external shape is found in the thin-film light emitting device 302 which is fixed to the integrated substrate 301, only the defective thin-film light emitting device can be exchanged for a new thin-film light emitting device, and thus manufacturing yield of final perfect product can be improved.

Except for the above-described points, the third embodiment is the same as the first or second embodiment.

### LED Printer

FIG. 19 shows a full-color LED printer 400 as an image forming apparatus, in which the present invention can be employed. The printer 400 has a yellow (Y) process unit 401, a magenta (M) process unit 402, a cyan (C) process unit 403, and a black (K) process unit 404, which are mounted following one another in tandem fashion. The cyan process unit 403, for example, includes a photosensitive drum 403a as a photosensitive body that turns in the direction indicated by an arrow, a charging unit 403b that supplies current to the photosensitive drum 403a to charge the surface thereof, an LED print head 403c that selectively illuminates the charged surface of the photosensitive drum 403a to form an electrostatic latent image, a developing unit 403d that supplies cyan toner particles to the surface of the photosensitive drum 403a to develop the electrostatic latent image, and a cleaning unit 403e that removes remaining toner from the photosensitive drum 403a after the developed image has been transferred to paper. The LED print head 403c includes, for example, the image exposing device described in any of the first to third embodiments. The other process units 401, 402, and 404 are similar in structure to the cyan process unit 403, but use different toner colors.

The paper 405 is held as a stack of sheets in a cassette 406. A hopping roller 407 feeds the paper 405 one sheet at a time toward a pair of rollers 408 and 410. After passing between these rollers, the paper 405 travels to a registration roller 411 and a pinch roller 409, which feed the paper 405 toward the yellow process unit 401. The paper 410 passes through the process units 401, 402, 403, and 404, traveling in each process unit between the photosensitive drum and a transfer roller 412. The transfer roller 412 attracts the toner image from the photosensitive drum 403a onto the paper 405. A full-color image is built up on the paper 405 in four stages, the yellow process unit 401 printing a yellow image, the magenta process unit 402 printing a magenta image, the cyan process unit 403 printing a cyan image, and the black process unit 404 printing a black image.

From the black process unit 404, the paper 405 travels through a fixing unit 413 for fixing the toner image to the paper 405. A pair of rollers 414 and 416 then feed the paper 405 upward to another pair of rollers 415 and 417, which deliver the paper 405 onto a stacker 418.

The invention being thus described, it will be obvious that the same may be varied in many ways. Such variations are not to be regarded as a departure from the spirit and scope of the invention, and all such modifications as would be obvious to one skilled in the art are intended to be included within the scope of following claims.

What is claimed is:

1. A semiconductor light-emitting element array device comprising:
a substrate;
a plurality of removable layers being disposed on the substrate; and
a thin-film semiconductor light-emitting device being disposed on each of the plurality of removable layers, being made of a different material from a surface material of the substrate, and having a semiconductor light-emitting element;
wherein the plurality of removable layers are made of a material which is capable of being etched by a selective chemical etching process.

2. The semiconductor light-emitting element array device according to claim 1, wherein the plurality of removable layers are made of a material selected from the group consisting of Al, Al₂O₃, SiO₂, SiN, and Ti.

3. The semiconductor light-emitting element array device according to claim 1, wherein
the surface material of the substrate is made of a material selected from the group consisting of SiO₂, SiN, and Ti; and
the plurality of removable layers are made of a material selected from the group consisting of Al and Al₂O₃.

4. The semiconductor light-emitting element array device according to claim 1, wherein
the surface material of the substrate is made of a material selected from the group consisting of Al and Al₂O₃; and
the plurality of removable layers are made of a material selected from the group consisting of SiO₂, SiN, and Ti.

5. The semiconductor light-emitting element array device according to claim 1, wherein the thin-film semiconductor light-emitting device is fixed on the removable layer by any of intermolecular force, hydrogen bonding, anodic bonding, and an adhesive agent.

6. The semiconductor light-emitting element array device according to claim 1, further comprising a smoothing layer being disposed on the removable layer;
wherein the thin-film semiconductor light-emitting device is fixed on the smoothing layer by any of intermolecular force, hydrogen bonding, and an adhesive agent.

7. The semiconductor light-emitting element array device according to claim 1, further comprising a bottom electrode layer being disposed on the removable layer;
wherein the thin-film semiconductor light-emitting device is fixed on the bottom electrode layer by any of intermolecular force, hydrogen bonding, anodic bonding, and an adhesive agent.

8. An image exposing device comprising:
an image exposing unit including the semiconductor light-emitting element array device of claim 1.

9. An image forming apparatus comprising:
the image exposing device of claim 8; and
a photosensitive body, on which an electrostatic latent image is formed by the image exposing device.

10. An image display apparatus comprising:
an image display unit including the semiconductor light-emitting element array device of claim 1.
